(19) United States
(12) Patent Application Publication
(10) Pub. No.: US 2024/0079476 A1
(43) Pub. Date: Mar. 7, 2024

(54) BACKSIDE POWER DELIVER NETWORK CONNECTION THROUGH DUMMY GATES

(71) Applicant: INTERNATIONAL BUSINESS MACHINES CORPORATION, Armonk, NY (US)

(72) Inventors: Tao Li, Slingerlands, NY (US); Ruilong Xie, Niskayuna, NY (US); Heng Wu, Santa Clara, CA (US); Julien Frougier, Albany, NY (US)

(21) Appl. No.: 17/902,275

(22) Filed: Sep. 2, 2022

(51) Int. Cl. H01L 29/66; H01L 21/8234; H01L 23/48; H01L 29/06; H01L 29/417; H01L 29/775; H01L 29/786

(52) U.S. Cl. CPC H01L 29/66545; H01L 21/823412; H01L 21/823418; H01L 23/481; H01L 29/0673; H01L 29/41733; H01L 29/775; H01L 29/78696

(57) ABSTRACT

A method of forming a backside power connection is provided. The method includes forming a plurality of sacrificial contact plugs and a plurality of sacrificial fill regions on a substrate, and forming a source/drain over a first sacrificial contact plug. The method further includes forming a replacement metal gate structure over a first sacrificial fill region, and forming an electrical contact to each of the replacement metal gate structure and the source/drain. The method further includes inverting the plurality of sacrificial contact plugs, source/drain, replacement metal gate structure, and substrate. The method further includes removing the first sacrificial contact plug and the first sacrificial fill region, and forming a first conductive contact to the source/drain and a second conductive contact to the replacement metal gate structure.

### BACKGROUND

The present invention generally relates to a back-side power distribution network (PDN) contacts, and more particularly to backside PDN connection through dummy gates with self-aligned backside contacts.

As a micro-through silicon via (uTSV) diameter increases, the keep-out-zone (KOZ) also increases. Through silicon vias (TSVs) can be formed as part of front-end-of-line (FEOL), middle, and back-end-of-line (BEOL) processes.

### SUMMARY

In accordance with an embodiment of the present invention, a method of forming a backside power connection is provided. The method includes forming a plurality of sacrificial contact plugs and a plurality of sacrificial fill regions on a substrate, and forming a source/drain over a first sacrificial contact plug. The method further includes forming a replacement metal gate structure over a first sacrificial fill region, and forming an electrical contact to each of the replacement metal gate structure and the source/drain. The method further includes inverting the plurality of sacrificial contact plugs, source/drain, replacement metal gate structure, and substrate. The method further includes removing the first sacrificial contact plug and the first sacrificial fill region, and forming a first conductive contact to the source/drain and a second conductive contact to the replacement metal gate structure.

In accordance with another embodiment of the present invention, a backside power connection device is provided. The device includes a first source/drain contact in electrical contact with a first source/drain, and a gate contact in electrical contact with a replacement metal gate structure. The device further includes a conductive contact in electrical contact with both the source/drain and the replacement metal gate structure on a side opposite the gate contact and the first source/drain contact.

In accordance with yet another embodiment of the present invention, a backside power connection device is provided. The device includes a back-end-of-line metallization layer on a carrier wafer, and a second ILD layer on the back-end-of-line metallization layer. The device further includes a first gate contact, a first source/drain contact, and a second source/drain contact in the second ILD layer, and in electrical contact with the back-end-of-line metallization layer. The device further includes a first source/drain on the first source/drain contact, and a second source/drain on the second source/drain contact. The device further includes a first replacement metal gate structure on and in electrical contact with the first gate contact, and a sacrificial contact plug on the first source/drain opposite the first source/drain contact. The device further includes a conductive contact on and in electrical contact with the replacement metal gate structure and the second source/drain.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a cross-sectional side view showing alternating nanosheet layers on a substrate, in accordance with an embodiment of the present invention;

FIG. 2 are perpendicular cross-sectional side views showing patterned nanosheet stacks on a substrate with intervening shallow trench isolation regions, in accordance with an embodiment of the present invention;

FIG. 3 are perpendicular cross-sectional side views showing dummy gate structures formed on the nanosheet stacks, and a buried insulating layer replacing a sacrificial layer beneath the nanosheet stacks, in accordance with an embodiment of the present invention;

FIG. 4 are perpendicular cross-sectional side views showing dummy fill regions formed in trenches between the nanosheet stacks, in accordance with an embodiment of the present invention;

FIG. 5 are perpendicular cross-sectional side views showing source/drains formed on dummy fill regions, in accordance with an embodiment of the present invention;

FIG. 6 are multiple perpendicular cross-sectional side views showing an interlayer dielectric (ILD) layer on the source/drains and dummy gate structures on different regions of the substrate, in accordance with an embodiment of the present invention;

FIG. 7 are multiple perpendicular cross-sectional side views showing removal of the dummy gate structures on a backside power connection region of the substrate, in accordance with an embodiment of the present invention;

FIG. 8 are multiple perpendicular cross-sectional side views showing formation of sacrificial fill regions on a backside power connection region of the substrate, in accordance with an embodiment of the present invention;

FIG. 9 are multiple perpendicular cross-sectional side views showing replacement of the dummy gate structures on the sacrificial fill regions on the backside power connection region of the substrate, in accordance with an embodiment of the present invention;

FIG. 10 are multiple perpendicular cross-sectional side views showing formation of replacement metal gate structures, in accordance with an embodiment of the present invention;

FIG. 11 are multiple perpendicular cross-sectional side views showing formation of middle-of-line connections, and back-end-of-line metallization layer formation, and carrier wafer bonding, in accordance with an embodiment of the present invention;

FIG. 12 are multiple perpendicular cross-sectional side views showing flipping of the substrate and carrier wafer, in accordance with an embodiment of the present invention;

FIG. 13 are multiple perpendicular cross-sectional side views showing removal of the substrate, buried layer, remaining active semiconductor layer and semiconductor mesa segments, in accordance with an embodiment of the present invention;

FIG. 14 are multiple perpendicular cross-sectional side views showing formation of a backside ILD layer, in accordance with an embodiment of the present invention;

FIG. 15 are multiple perpendicular cross-sectional side views showing backside contact opening patterning in the backside ILD layer to expose select sacrificial contact plug(s) and sacrificial fill regions, in accordance with an embodiment of the present invention;

FIG. 16 are multiple perpendicular cross-sectional side views showing removal of the exposed sacrificial contact plug(s) and sacrificial fill regions to form contact trenches, in accordance with an embodiment of the present invention;

FIG. 17 are multiple perpendicular cross-sectional side views showing formation of the backside conductive contacts in the contact trenches, in accordance with an embodiment of the present invention; and

FIG. 18 are multiple perpendicular cross-sectional side views showing formation of the backside power delivery network to the conductive contacts, in accordance with an embodiment of the present invention.

### DETAILED DESCRIPTION

Principles and embodiments of the present invention relate to utilizing dummy gate structures to form back-side electrical connections to save on chip area and avoid stresses that can warp the wafer. Dummy devices may be used for power connections between back-end-of-line (BEOL) and a back-side power delivery network (BSPDN), which avoids the use of wafer area for independent through silicon vias (TSVs).

Compared with having a micro-TSV or nano-TSV, a dummy device built in power connection can greatly reduce the area used for TSV keep-out zones (KOZ), and can help reduce fabrication process complexity.

In one or more embodiments, a dummy placeholder can be formed in source/drain regions of devices and removed after flipping the wafer to form self-aligned back-side electrical contacts.

In various embodiments, a backside power rail can connect to a frontside BEOL of a transistor through a dummy gate region, where nanosheets under the dummy gate region have been removed in forming the electrical contact.

Exemplary applications/uses to which the present invention can be applied include, but are not limited to: digital logic structures and device (e.g., gates, central processing units, etc.) and memory structures and device (e.g., static random access memory (SRAM), dynamic random access memory (DRAM), etc.).

It is to be understood that aspects of the present invention will be described in terms of a given illustrative architecture; however, other architectures, structures, substrate materials and process features and steps can be varied within the scope of aspects of the present invention.

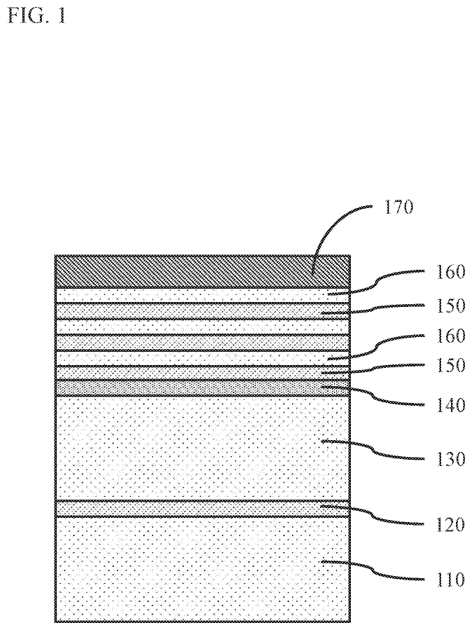

Referring now to the drawings in which like numerals represent the same or similar elements and initially to FIG. 1, FIG. 1 is a cross-sectional side view showing alternating nanosheet layers on a substrate, in accordance with an embodiment of the present invention.

In one or more embodiments, alternating sacrificial layers 150 and nanosheet layers 160 can be formed on a substrate 110. The sacrificial layers 150 and nanosheet layers 160 can be formed on a bottom sacrificial layer 140 between the sacrificial layers 150 and nanosheet layers 160 and an active semiconductor layer 130. A buried layer 120 can be between the substrate 110 and the active semiconductor layer 130. In various embodiments, a masking layer 170 can be formed on the alternating sacrificial layers 150 and nanosheet layers 160.

In various embodiments, the substrate 110 and active semiconductor layer 130 can each be a semiconductor material, for example, silicon (Si), silicon-germanium (SiGe), silicon carbide (SiC), or III-V compound semiconductor material (e.g., gallium-arsenide (GaAs)). The substrate 110 can be a semiconductor-on-insulator (SeOI) substrate, where the buried layer 120 can be a buried electrical insulator layer (e.g., BOX layer).

In various embodiments, the buried layer 120 can be formed on the substrate 110 or between the substrate 110 and the active semiconductor layer 130, where the buried layer 120 can be a buried oxide layer (BOX) or a buried silicon-germanium (SiGe) partition layer.

In various embodiments, the active semiconductor layer 130 can be the same semiconductor material as the substrate 110 or a different semiconductor material formed on the buried layer 120, for example, a semiconductor material epitaxially grown on a buried silicon-germanium partition layer.

In various embodiments, the sacrificial layers 150 can be silicon-germanium (SiGe) layers having a germanium concentration sufficient to allow selective etching and removal relative to the bottom sacrificial layer 140 and the nanosheet layers 160. The nanosheet layers 160 can be a semiconductor material, including, but not limited to, silicon (Si), where the sacrificial layers 150 can be selectively etched relative to the nanosheet layer material.

In various embodiments, the bottom sacrificial layer 140 can be silicon-germanium (SiGe) layers having a germanium concentration sufficient to allow selective etching and removal relative to the active semiconductor layer 130, nanosheet layers 160, and the sacrificial layers 150. In various embodiments, the bottom sacrificial layer 140 can be silicon-germanium (SiGe) layer having a germanium concentration of greater than 50 atomic percent (at. %), whereas the sacrificial layers 150 can be silicon-germanium (SiGe) layer having a germanium concentration of less than 40 at. %.

In various embodiments, the masking layer 170 can be a hardmask, dielectric material, for example, silicon nitride (SiN), silicon boronitride (SiBN), etc., where the masking layer 170 can have multiple layers of masking materials.

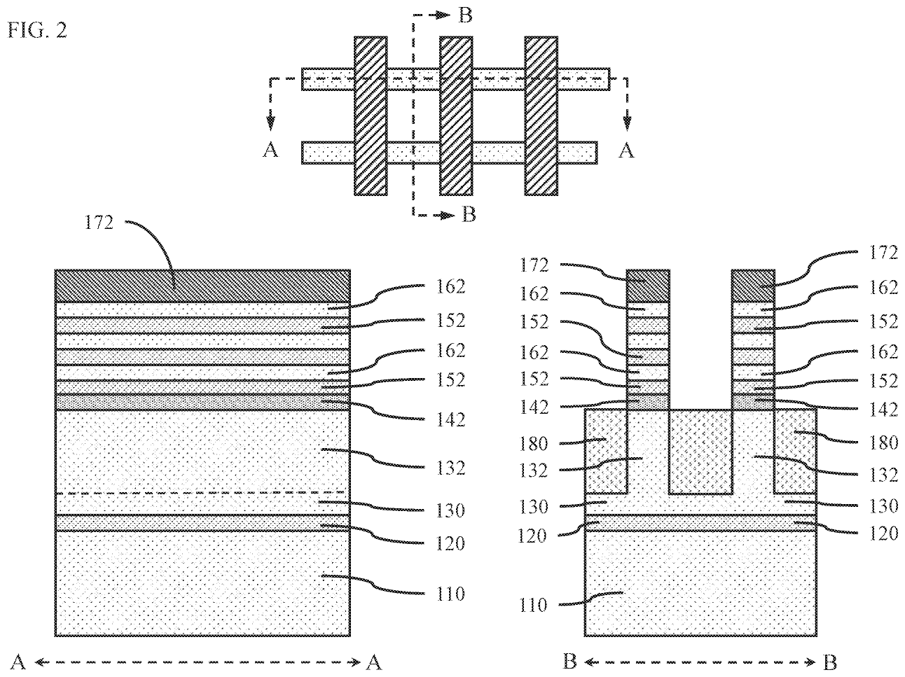

FIG. 2 are perpendicular cross-sectional side views showing patterned nanosheet stacks on a substrate with intervening shallow trench isolation regions, in accordance with an embodiment of the present invention.

In one or more embodiments, the masking layer 170, sacrificial layers 150, nanosheet layers 160, and bottom sacrificial layer 140 can be patterned, for example, by lithography and etching (e.g., reactive ion etching (RIE)), to form nanosheet templates 172 on underlying sacrificial sections 152 and nanosheet layer sections 162. The bottom sacrificial layer 140 can be etched to form a bottom sacrificial section 142, and the active semiconductor layer 130 can be etched to form trenches with an active semiconductor mesa 132 beneath the bottom sacrificial section 142 and patterned nanosheet stack of alternating sacrificial sections 152 and nanosheet layer sections 162.

In one or more embodiments, shallow trench isolation regions 180 can be formed adjacent to the active semiconductor mesa(s) 132, where a top surface of the shallow trench isolation regions 180 can be at or above the bottom surface of the bottom sacrificial section 142, where the top surface of the shallow trench isolation regions 180 is at or below the middle of the bottom sacrificial section 142. The shallow trench isolation regions 180 can be formed by a directional deposition and selective etch-back. In various embodiments, a portion of the active semiconductor layer 130 can remain between the bottom surface of the shallow trench isolation regions 180 and the top surface of the buried layer 120, where the etching of the active semiconductor layer 130 does not extend all the way down to the buried layer 120.

In various embodiments, the shallow trench isolation regions 180 can be formed of an electrically insulating dielectric material, for example, silicon oxide (SiOₓ), silicon oxynitride (SiON), and combinations thereof.

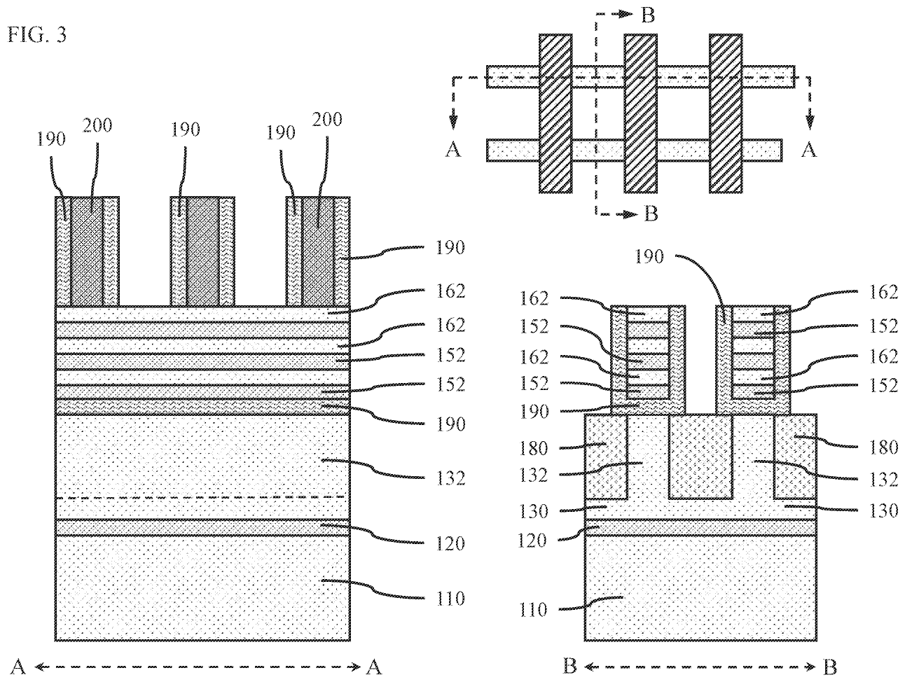

FIG. 3 are perpendicular cross-sectional side views showing dummy gate structures formed on the nanosheet stacks, and a buried insulating layer replacing a sacrificial layer beneath the nanosheet stacks, in accordance with an embodiment of the present invention.

In one or more embodiments, the nanosheet templates 172 can be selectively removed to expose the underlying nanosheet stack.

In one or more embodiments, the bottom sacrificial section 142 can be selectively removed, for example, using a selective isotropic etch (e.g., wet chemical etch) that can form a channel beneath the nano sheet stack of alternating sacrificial sections 152 and nanosheet layer sections 162.

In one or more embodiments, dummy gate structures including dummy gate sidewalls 190 and a dummy gate fill 200 can be formed on the stack of alternating sacrificial sections 152 and nanosheet layer sections 162. One or more dummy gate fills 200 can be formed on the stack of alternating sacrificial sections 152 and nanosheet layer sections 162, for example, by forming and patterning a dummy gate layer.

In one or more embodiments, the dummy gate sidewalls 190 be formed by a conformal deposition (e.g., atomic layer deposition (ALD)) on the one or more dummy gate fills 200 and stack of alternating sacrificial sections 152 and nanosheet layer sections 162, and can also fill in the channel formed by removing the bottom sacrificial section 142 to form a bottom dielectric insulator (BDI) 190. The dummy gate sidewalls 190 can cover the sidewalls of the stack of alternating sacrificial sections 152 and nanosheet layer sections 162 and extend over portions of the shallow trench isolation regions 180.

In various embodiments, the dummy gate fills 200 can be amorphous silicon (a-Si), and the dummy gate sidewalls 190 can be a dielectric material, for example, silicon oxide (SiOₓ), silicon oxynitride (SiON), silicon oxycarbide (SiOC), silicon nitride (SiN), and combinations thereof.

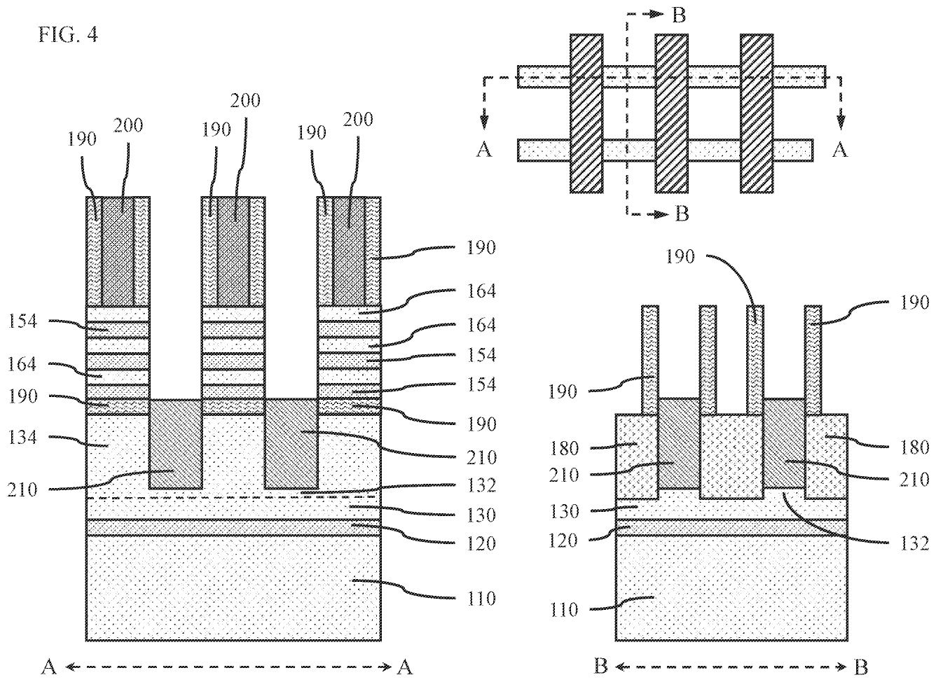

FIG. 4 are perpendicular cross-sectional side views showing dummy fill regions formed in trenches between the nanosheet stacks, in accordance with an embodiment of the present invention.

In one or more embodiments, portions of the sacrificial sections 152 and nanosheet layer sections 162 can be exposed between the dummy gate sidewalls 190 of the dummy gate structure. The exposed portions of the sacrificial sections 152 and nanosheet layer sections 162 can be removed using a selective directional etch (e.g., RIE) to form a stack of alternating sacrificial segments 154 and nanosheet layer segments 164. Removal of the exposed portions of the sacrificial sections 152 and nanosheet layer sections 162 can expose a portion of the dummy gate sidewalls and BDI 190, where the BDI 190 can be removed using a selective directional etch (e.g., RIE) to expose the underlying portion of the active semiconductor mesa 132 between the dummy gate structures.

In various embodiments, a portion of the active semiconductor mesa 132 can be removed to form semiconductor mesa segments 134 separated by mesa cavities. A portion of the active semiconductor mesa 132 can remain between shallow trench isolation regions 180, and between the semiconductor mesa segments 134. A portion of the active semiconductor layer 130 can remain beneath the semiconductor mesa segments 134 and active semiconductor mesa 132.

In one or more embodiments, a sacrificial contact plug 210 can be formed in each of the mesa cavities between the semiconductor mesa segments 134, where the sacrificial contact plug 210 can be formed by a directional deposition and etch-back. The top surface of the sacrificial contact plug 210 can be at or below the top surface of the portions of the dummy gate sidewalls 190 beneath the stack of alternating sacrificial segments 154 and nanosheet layer segments 164. The top surface(s) of the sacrificial contact plug(s) 210 can extend above the top surfaces of the shallow trench isolation regions 180, and cover a lower portion of the inside sidewalls of the dummy gate sidewalls 190.

In various embodiments, the sacrificial contact plug(s) 210 can be made of a dielectric material, including, but not limited to, silicon carbide (SiC), silicon germanium (SiGe), and combinations thereof, where the sacrificial contact plug(s) 210 can be selectively removed relative to the shallow trench isolation regions 180, the dummy gate sidewalls 190, and the inner spacers 220.

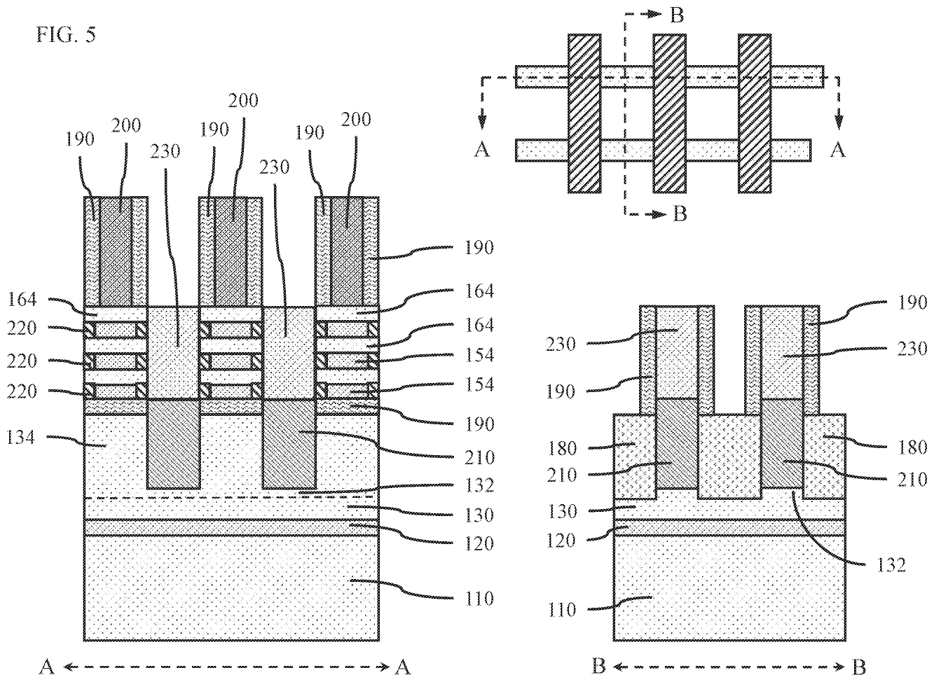

FIG. 5 are perpendicular cross-sectional side views showing source/drains formed on dummy fill regions, in accordance with an embodiment of the present invention.

In various embodiments, a portion of each of the sacrificial segments 154 can be removed to form recesses, where a dielectric insulating material can be formed in the recesses to form inner spacers 220. The inner spacers 220 can be formed by a conformal deposition (e.g., ALD), and an isotropic etch-back. In various embodiments, the dielectric insulating material for the inner spacers 220 can be, for example, silicon nitride (SiN), silicon boro carbonitride (SiBCN), silicon oxy carbide (SiCO), silicon oxy carbonitride (SiOCN), and combinations thereof. In various embodiments, the dummy gate sidewalls 190 and the inner spacers 220 can be the same material.

In one or more embodiments, source/drains 230 can be formed on the sacrificial contact plugs 210 and between adjacent sacrificial segments 154 and nanosheet layer segments 164, where the source/drains 230 can be formed by lateral epitaxial growth from the exposed sides of the nanosheet layer segments 164. The source/drains 230 can be suitably doped to form n-type or p-type devices. The inner spacers 220 can electrically isolate the sacrificial segments 154 from the source/drains 230.

In various embodiments, a portion of the dummy gate sidewalls 190 can cover the sidewalls of the source/drains 230.

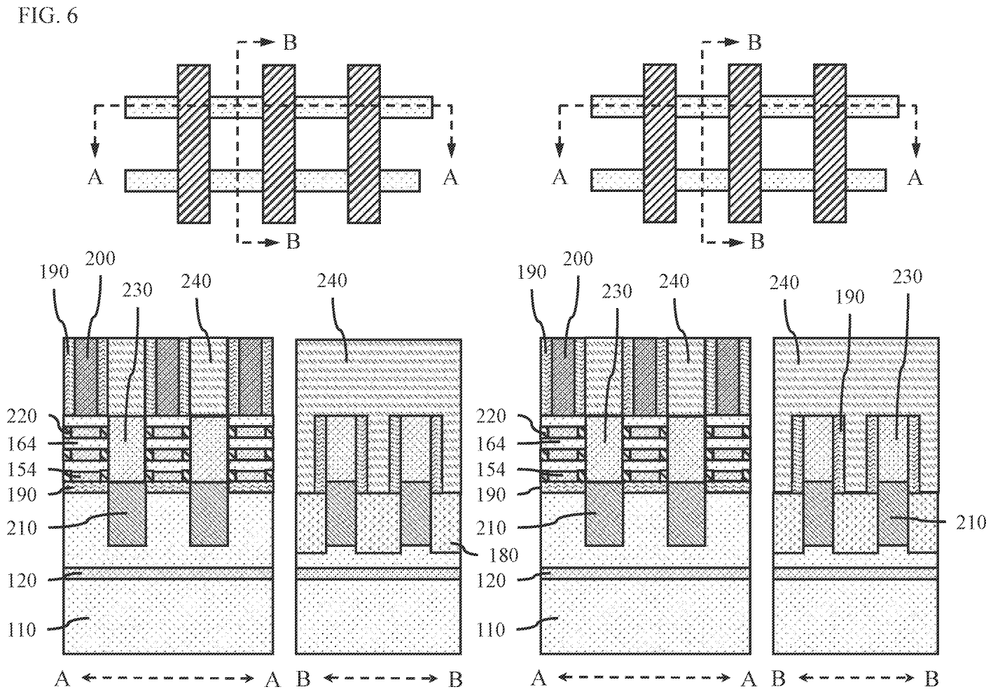

FIG. 6 are multiple perpendicular cross-sectional side views showing an interlayer dielectric (ILD) layer formed on the source/drains and dummy gate structures on different regions of the substrate, in accordance with an embodiment of the present invention.

In one or more embodiments, an interlayer dielectric (ILD) layer 240 can be formed on the source/drains 230 and dummy gate sidewalls 190 of the dummy gate structures on different regions of the substrate, where the ILD layer 240 can be formed by a blanket deposition (e.g., chemical vapor deposition (CVD)). The interlayer dielectric (ILD) layer 240 can fill in the spaces between the dummy gate sidewalls 190 and above the source/drains 230. In various embodiments, the interlayer dielectric (ILD) layer 240 can be an electrically insulating dielectric layer, for example, silicon oxide (SiOₓ). In various embodiments, the ILD layer 240 can be planarized using a chemical-mechanical polishing (CMP) to provide a smooth, uniform surface, where the tops of the dummy gate fill 200 are exposed.

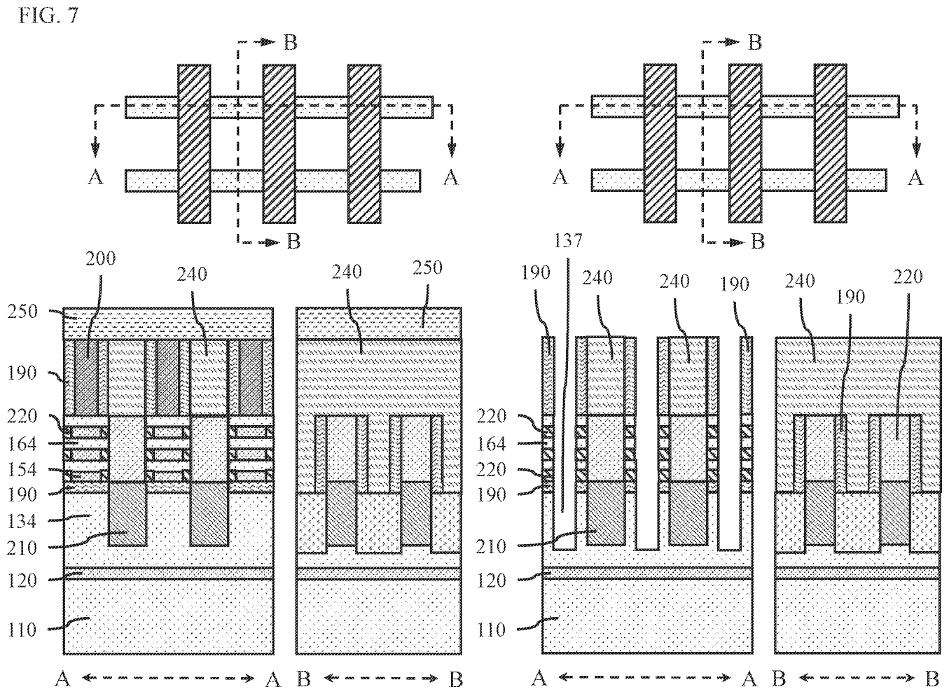

FIG. 7 are multiple perpendicular cross-sectional side views showing removal of the dummy gate structures on a backside power connection region of the substrate, in accordance with an embodiment of the present invention.

In one or more embodiments, a protective cap layer 250 can be formed on the interlayer dielectric (ILD) layer 240 and dummy gate structures including the dummy gate fill 200, where the protective cap layer 250 can be formed by a blanket deposition. In various embodiments, the protective cap layer 250 can be a dielectric material that can be selectively removed relative to the ILD layer 240, the dummy gate sidewalls 190, and the dummy gate fill 200. In various embodiments, the protective cap layer 250 can be, for example, silicon nitride (SiN), an organic planarization layer (OPL), or a combination thereof, where the protective cap layer 250 can be selectively etched relative to the ILD layer 240.

In various embodiments, portions of the protective cap layer 250 can be removed from different regions through masking and a selective etch to expose dummy gate structures in a region to be used for forming backside power connections.

In one or more embodiments, the one or more dummy gate fills 200 exposed by removal of the portion(s) of the protective cap layer 250 can be removed using a selective etch to expose a top-most segment of the sacrificial segments 154 and nanosheet layer segments 164.

In one or more embodiments, the exposed sacrificial segments 154 and nanosheet layer segments 164 can be removed using selective, directional etches (e.g., RIE) to expose an underlying portion of the dummy gate sidewalls 190. Portions of the nanosheet layer segments 164 may remain between the inner spacers 220.

In various embodiments, the portion of the dummy gate sidewalls (BDI) 190 below the removed portions of the sacrificial segments 154 and nanosheet layer segments 164 can be removed by a selective etch to expose the underlying semiconductor mesa segments 134. Portions of the semiconductor mesa segments 134 can be removed using a selective directional etch (e.g., RIE) to form channels 137 in the semiconductor mesa segments 134.

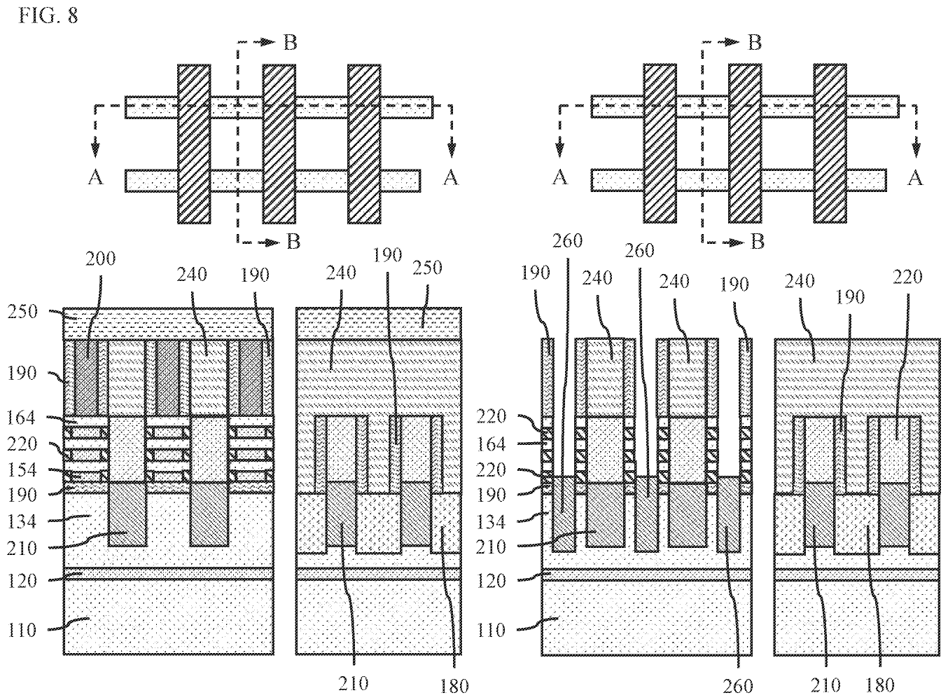

FIG. 8 are multiple perpendicular cross-sectional side views showing formation of sacrificial fill regions on a backside power connection region of the substrate, in accordance with an embodiment of the present invention.

In one or more embodiments, sacrificial fill regions 260 can be formed in the channels 137, where the sacrificial fill regions 260 can be formed by a directional deposition and etch-back. The sacrificial fill regions 260 can have a top surface that is above the portion of the dummy gate sidewalls 190, where the top surface of the sacrificial fill regions 260 can be between the top and bottom surfaces of the bottom-most inner spacers 220. Sides of the nanosheet layer segments 164 and inner spacers 220 can be exposed in the upper portion of the channel 137.

In various embodiments, the sacrificial fill regions 260 can be the same material as the sacrificial contact plug 210.

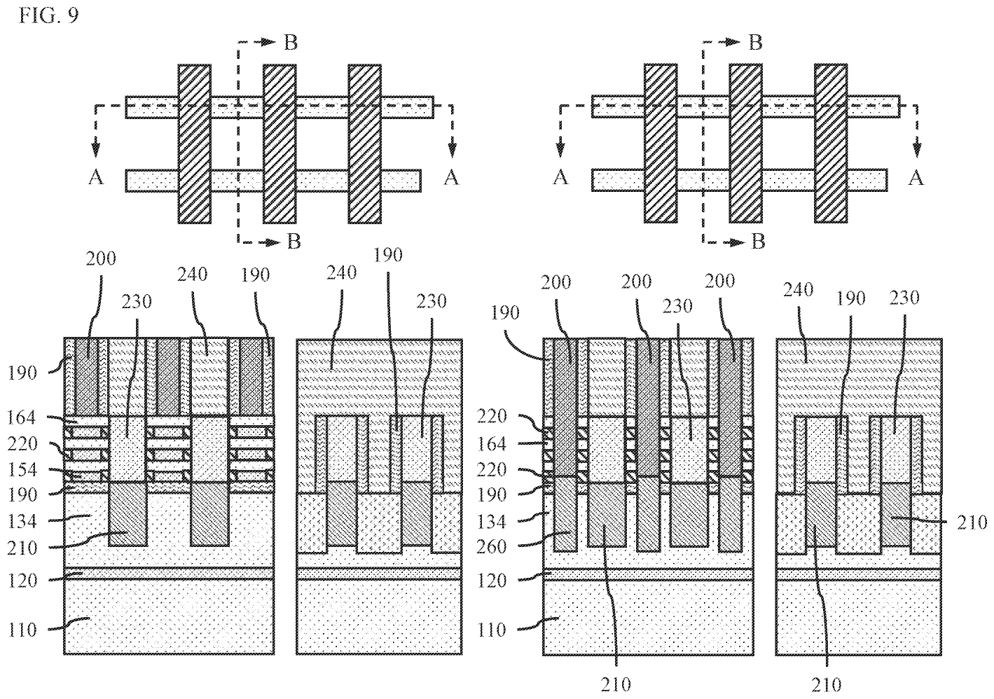

FIG. 9 are multiple perpendicular cross-sectional side views showing replacement of the dummy gate structures on the sacrificial fill regions on the backside power connection region of the substrate, in accordance with an embodiment of the present invention.

In one or more embodiments, the protective cap layer 250 can be removed.

In one or more embodiments, dummy gate fills 200 can be formed in the upper portion of the channels 137, where the dummy gate fills 200 can be formed on the sacrificial fill regions 260.

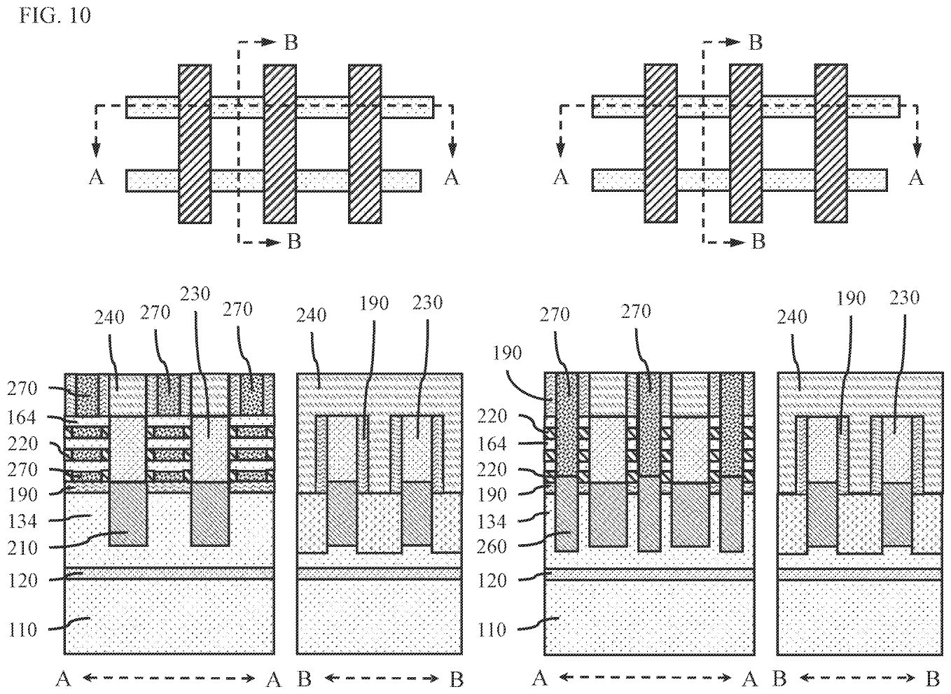

FIG. 10 are multiple perpendicular cross-sectional side views showing formation of replacement metal gate structures, in accordance with an embodiment of the present invention.

In one or more embodiments, the dummy gate fills 200 can be removed from the different regions by a selective etch. This can expose the sacrificial segments 154 and nanosheet layer segments 164 in a device region, and the sacrificial fill regions 260 in the backside power connection region.

In one or more embodiments, the sacrificial segments 154 can be removed by selective, isotropic etching (e.g., wet chemical etching).

In one or more embodiments, replacement metal gate structures 270 can be formed in the spaces created by removal of the dummy gate fill 200 and sacrificial segments 154, where the replacement metal gate structures 270 can be formed by conformal deposition (e.g., ALD). In various embodiments, the replacement metal gate structures 270 can include a gate dielectric layer and a conductive gate fill. The gate dielectric layer can be formed on the nanosheet layer segments 164 using a conformal deposition. A conductive gate fill can be formed on the gate dielectric layer.

In various embodiments, the gate dielectric layer can be a high-k dielectric material, and the conductive gate fill can be, for example, a metal having an intended conductance and/or work function, for example, tantalum (Ta), titanium (Ti), tungsten (W), etc.

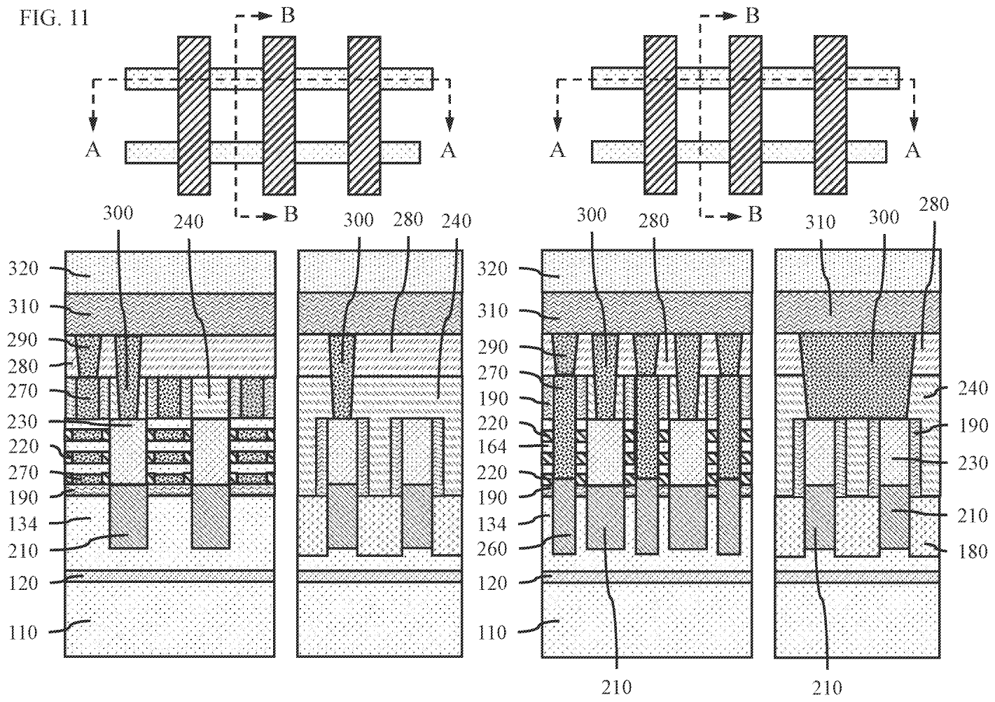

FIG. 11 are multiple perpendicular cross-sectional side views showing formation of middle-of-line connections, and back-end-of-line metallization layer formation, and carrier wafer bonding, in accordance with an embodiment of the present invention.

In one or more embodiments, one or more gate contacts 290 can be formed in a second ILD layer 280, where the gate contacts 290 form electrical connections to the replacement metal gate structures 270. The second ILD layer 280 can be an electrically insulating dielectric layer (e.g., SiOₓ) formed by a blanket deposition (e.g., CVD) on the interlayer dielectric (ILD) layer 240.

In one or more embodiments, one or more source/drain contacts 300 can be formed in a second ILD layer 280, where the source/drain contacts 300 form electrical connections to the source/drains 230. In various embodiments, the gate contacts 290 and source/drain contacts 300 can be a metal, for example, copper (Cu), tungsten (W), tantalum (Ta), molybdenum (Mo), cobalt (Co), and combinations thereof.

In one or more embodiments, a back-end-of-line metallization layer 310 can be formed on the second ILD layer 280, where the back-end-of-line metallization layer 310 can include additional metal lines and vias for electrical connection of the semiconductor devices.

In one or more embodiments, a carrier wafer 320 can be attached to the top of the back-end-of-line metallization layer 310, where the carrier wafer 320 can be wafer bonded to the metallization layer 310.

In various embodiments, the carrier wafer 320 can be a semiconductor wafer having a thickness sufficient to transfer and transport the attached substrate 110 and intervening layers and features.

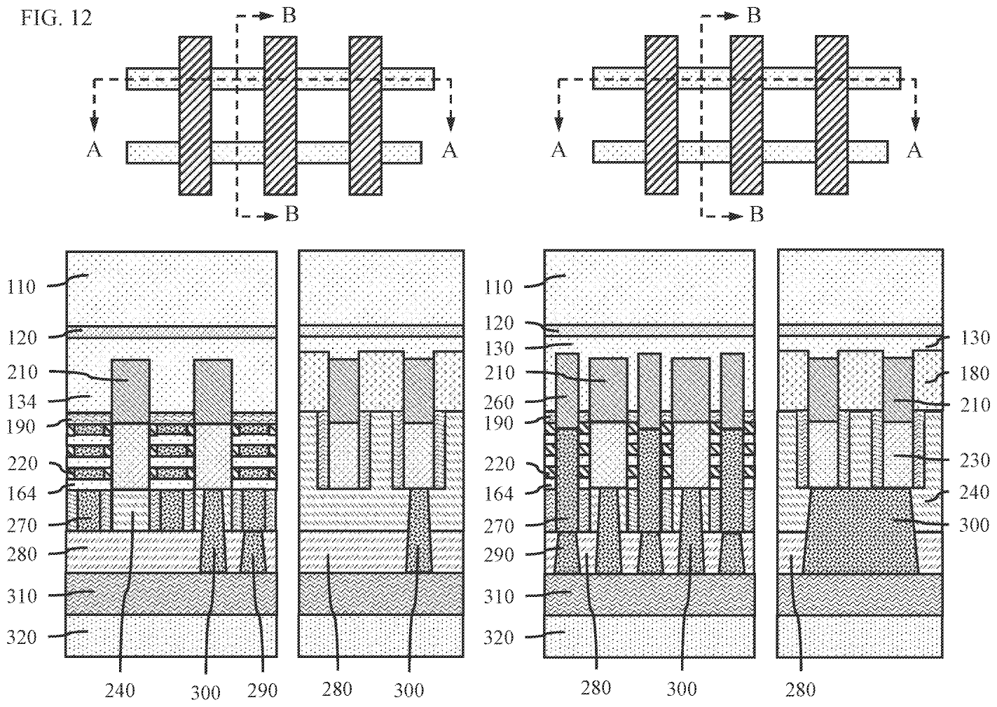

FIG. 12 are multiple perpendicular cross-sectional side views showing flipping of the substrate and carrier wafer, in accordance with an embodiment of the present invention.

In one or more embodiments, the substrate 110 with the bonded carrier wafer 320 can be flipped 180 degrees (i.e., inverted), so the bottom surface of the substrate 110 becomes the top working surface, and the carrier wafer 320 becomes the support for the intervening layers and devices.

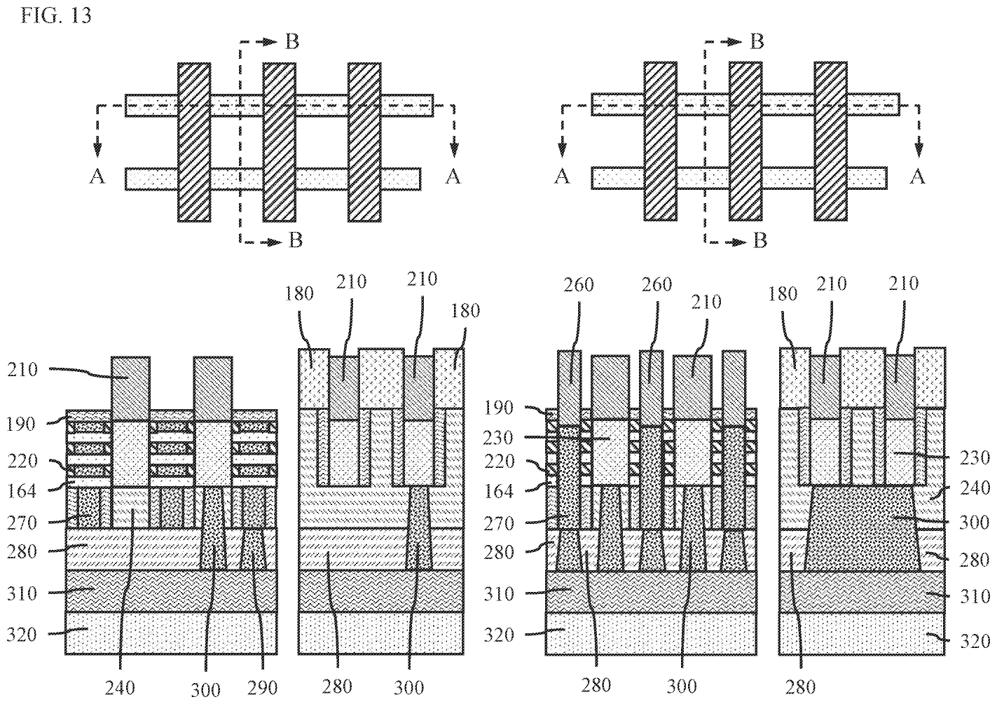

FIG. 13 are multiple perpendicular cross-sectional side views showing removal of the substrate, buried layer, remaining active semiconductor layer and semiconductor mesa segments, in accordance with an embodiment of the present invention.

In one or more embodiments, the substrate 110, buried layer 120, remaining active semiconductor layer 130, and semiconductor mesa segments 134 can be removed by selective etching, where the removal of the remaining active semiconductor layer 130 and semiconductor mesa segments 134 can expose the sacrificial contact plug(s) 210 and sacrificial fill region(s) 260. The shallow trench isolation regions 180 can also be exposed.

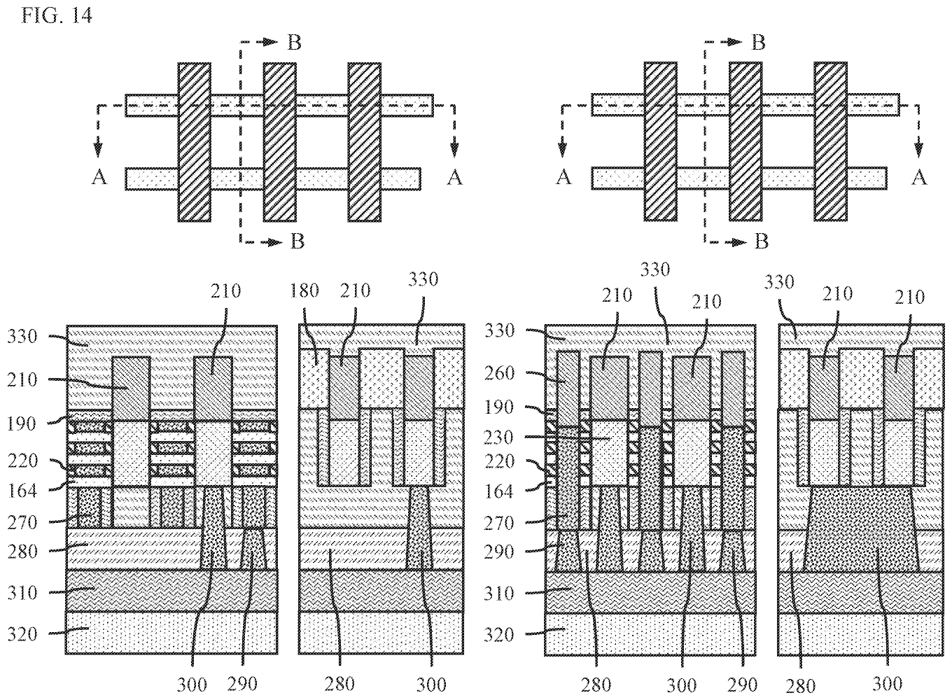

FIG. 14 are multiple perpendicular cross-sectional side views showing formation of a backside ILD layer, in accordance with an embodiment of the present invention.

In one or more embodiments, backside ILD layer 330 can be formed on the exposed shallow trench isolation regions 180, sacrificial contact plug(s) 210, and sacrificial fill region(s) 260. In various embodiments, the backside ILD layer 330 can be an electrically insulating, dielectric material (e.g., SiOₓ) formed by a blanket deposition (e.g., CVD).

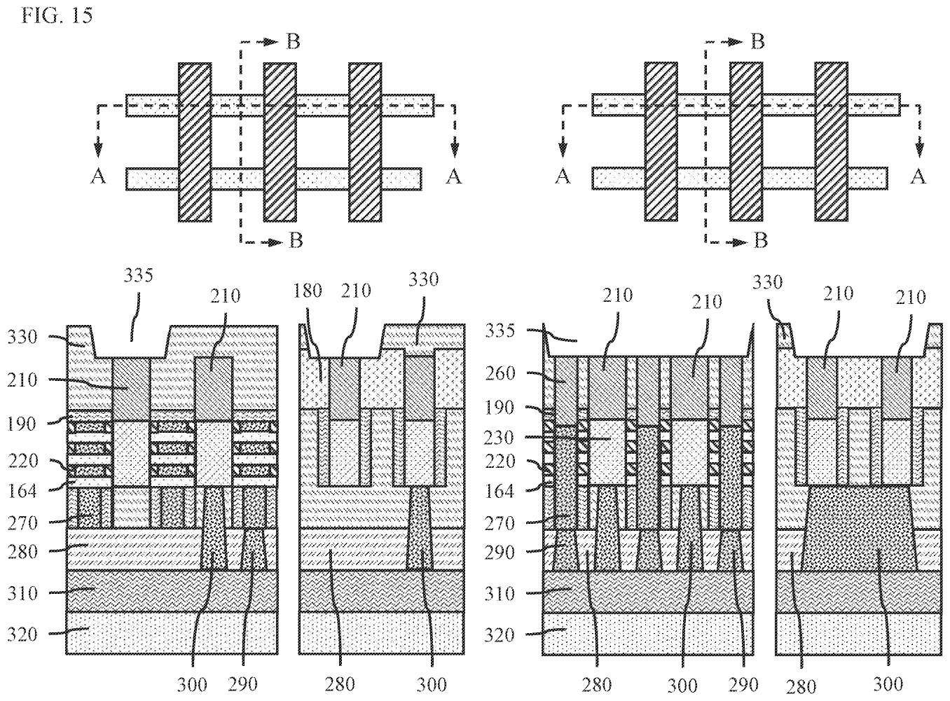

FIG. 15 are multiple perpendicular cross-sectional side views showing backside contact opening patterning in the backside ILD layer to expose select sacrificial contact plug(s) and sacrificial fill regions, in accordance with an embodiment of the present invention.

In one or more embodiments, the backside ILD layer 330 can be patterned to form openings 335 above predetermined sacrificial contact plug(s) 210 and sacrificial fill regions 260, where removal of the portions of the backside ILD layer 330 can expose the underlying sacrificial contact plug(s) 210 and sacrificial fill regions 260. The backside ILD layer 330 can be patterned through lithography and etching.

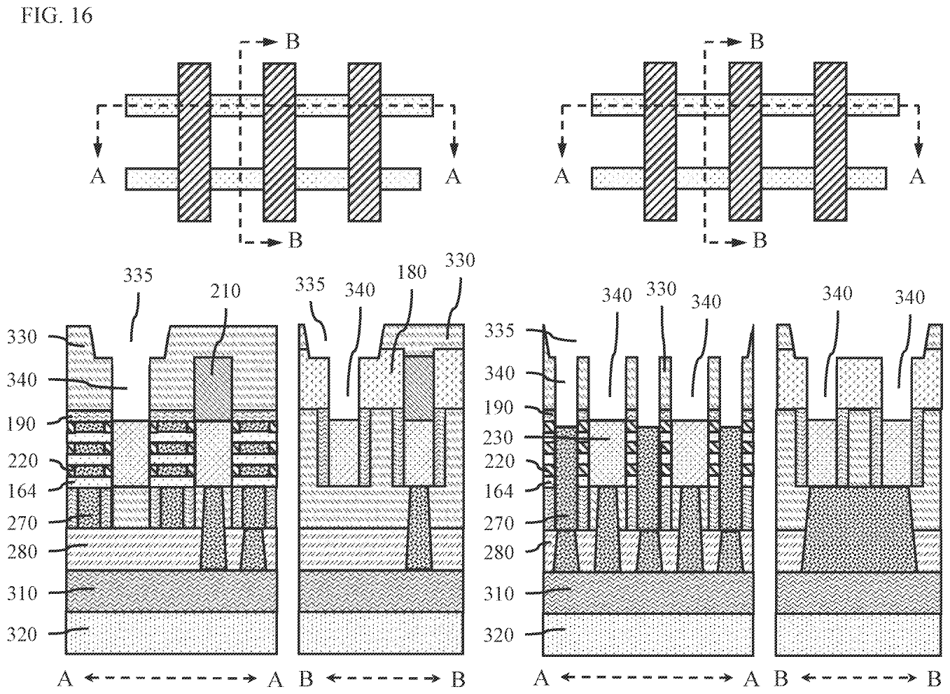

FIG. 16 are multiple perpendicular cross-sectional side views showing removal of the exposed sacrificial contact plug(s) and sacrificial fill regions to form contact trenches, in accordance with an embodiment of the present invention.

In one or more embodiments, the exposed sacrificial contact plug(s) 210 and sacrificial fill regions 260 can be removed using selective etching to form contact trenches 340. The contact trenches 340 can expose the underlying source/drains 230, and replacement metal gate structures 270.

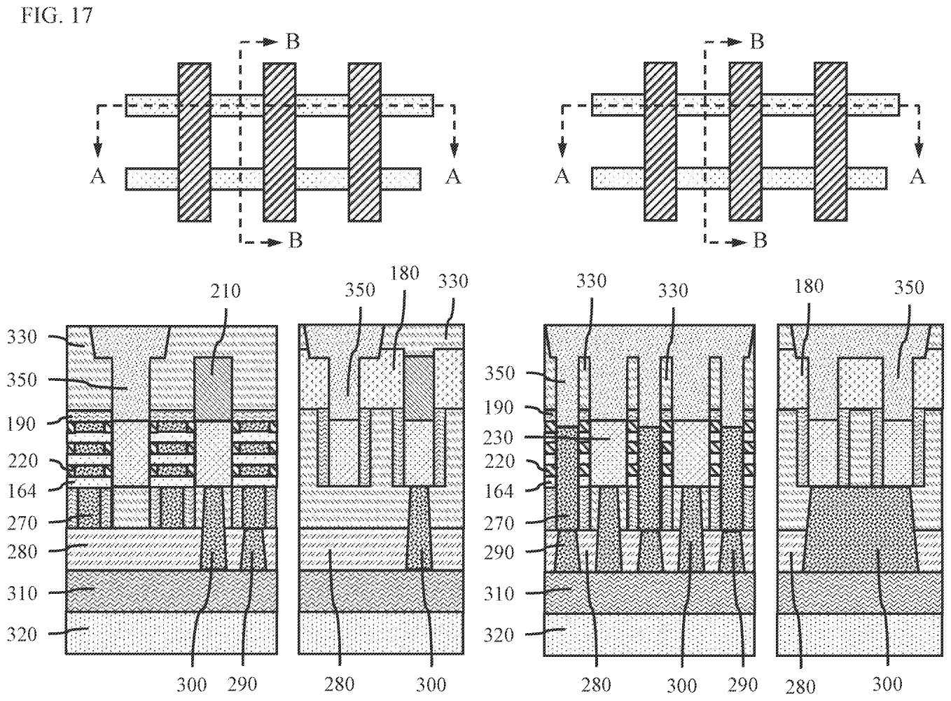

FIG. 17 are multiple perpendicular cross-sectional side views showing formation of the backside conductive contacts in the contact trenches, in accordance with an embodiment of the present invention.

In one or more embodiments, the contact trenches 340 and openings 335 can be filled with a conductive metal, for example, copper (Cu), tungsten (W), tantalum (Ta), molybdenum (Mo), cobalt (Co), and combinations thereof, using a conformal deposition (e.g., ALD) to form conductive contacts 350.

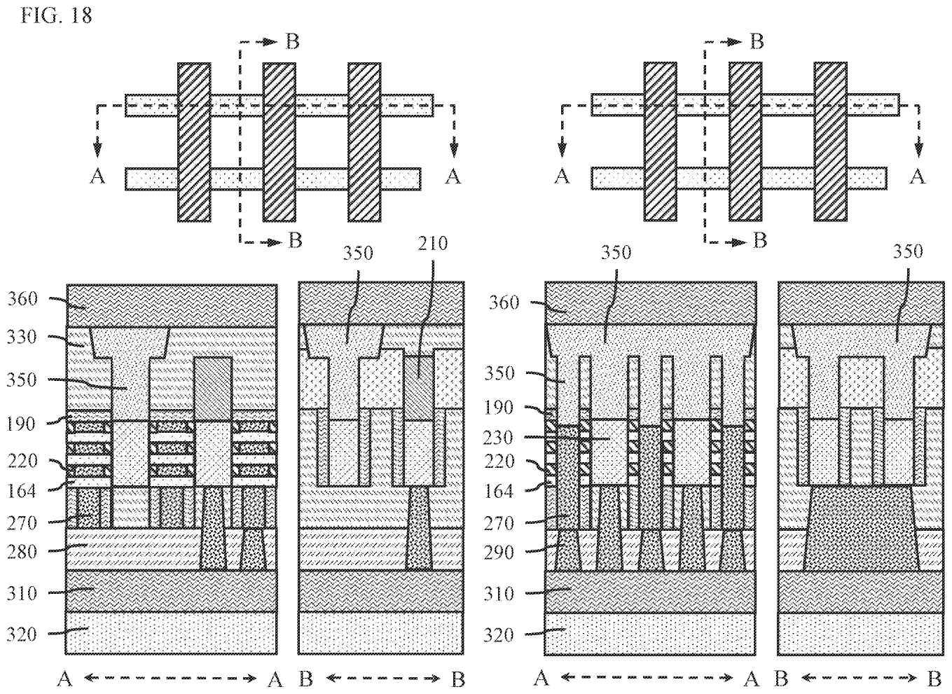

FIG. 18 are multiple perpendicular cross-sectional side views showing formation of the backside power delivery network to the conductive contacts, in accordance with an embodiment of the present invention.

In one or more embodiments, a backside power delivery network (BSPDN) 360 can be formed on and to the conductive contacts 350, where a backside power rail can connect to a frontside BEOL connection of a transistor through the conductive contacts 350, replacement metal gate structures 270, source/drains 230, gate contacts 290, and source/drain contacts 300 of a dummy device.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The terminology used herein is for the purpose of describing particular embodiments only and is not tended to be limiting of example embodiments. As used herein, the singular forms “a,” ‘an’ and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence car addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both siltation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of a device and method of fabricating the device (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

What is claimed is:

1. A method of forming a backside power connection, comprising:
forming a plurality of sacrificial contact plugs and a plurality of sacrificial fill regions on a substrate;
forming a source/drain over a first sacrificial contact plug;
forming a replacement metal gate structure over a first sacrificial fill region;
forming an electrical contact to each of the replacement metal gate structure and the source/drain;
inverting the plurality of sacrificial contact plugs, source/drain, replacement metal gate structure, and substrate;
removing the first sacrificial contact plug and the first sacrificial fill region; and
forming a first conductive contact to the source/drain and a second conductive contact to the replacement metal gate structure.

2. The method of claim 1, further comprising form a backside power delivery network (BSPDN) on and in electrical contact with the first conductive contact and the second conductive contact.

3. The method of claim 2, wherein the first sacrificial fill region and the replacement metal gate structure are formed by removing portions of sacrificial segments, nanosheet layer segments, and a portion of a semiconductor mesa segment to form a channel, forming the first sacrificial fill region in the channel adjoining the semiconductor mesa segment, and forming the replacement metal gate structure on the first sacrificial fill region.

4. The method of claim 3, wherein the first sacrificial contact plug and source/drain are formed by removing portions of sacrificial segments, nanosheet layer segments, dummy gate sidewall, and a portion of an active semiconductor mesa to form a mesa cavity between semiconductor mesa segments, forming the first sacrificial contact plug in the mesa cavity adjoining the semiconductor mesa segments, and forming the source/drain on the first sacrificial contact plug.

5. The method of claim 4, wherein the first sacrificial contact plug and the first sacrificial fill region are both a semiconductor material selected from the group consisting of silicon carbide (SiC), silicon germanium (SiGe), and combinations thereof.

6. The method of claim 5, further comprising forming a backside ILD layer on the shallow trench isolation regions, the sacrificial contact plugs, and the sacrificial fill regions.

7. The method of claim 6, further comprising forming openings in the backside ILD layer.

8. The method of claim 7, further comprising removing the first sacrificial fill region and the first sacrificial contact plug to form contact trenches for the first conductive contact and the second conductive contact.

9. The method of claim 8, wherein a source/drain contact is electrically connected to a back-end-of-line metallization layer and the source/drain.

10. A backside power connection device, comprising:
a first source/drain contact in electrical contact with a first source/drain;
a gate contact in electrical contact with a replacement metal gate structure; and
a conductive contact in electrical contact with both the source/drain and the replacement metal gate structure on a side opposite the gate contact and the first source/drain contact.

11. The backside power connection device of claim 10, further comprising a back-end-of-line metallization layer on and in electrical contact with the first source/drain contact and the gate contact.

12. The backside power connection device of claim 11, further comprising a sacrificial contact plug on a second source/drain, and a second source/drain contact in electrical contact with the second source/drain on a side opposite the sacrificial contact plug.

13. The backside power connection device of claim 12, further comprising dummy gate sidewalls adjacent to the replacement metal gate structure.

14. The backside power connection device of claim 13, further comprising a back-end-of-line metallization layer on the gate contact, the first source/drain contact, and the second source/drain contact.

15. The backside power connection device of claim 14, further comprising a backside power delivery network (BSPDN) on and in electrical contact with the conductive contact.

16. The backside power connection device of claim 15, further comprising nanosheet layer segments on opposite sides of the replacement metal gate structure.

17. A backside power connection device, comprising:
a back-end-of-line metallization layer on a carrier wafer;
a second ILD layer on the back-end-of-line metallization layer;
a first gate contact, a first source/drain contact, and a second source/drain contact in the second ILD layer, and in electrical contact with the back-end-of-line metallization layer;
a first source/drain on the first source/drain contact;
a second source/drain on the second source/drain contact;
a first replacement metal gate structure on and in electrical contact with the first gate contact;
a sacrificial contact plug on the first source/drain opposite the first source/drain contact; and
a conductive contact on and in electrical contact with the replacement metal gate structure and the second source/drain.

18. The backside power connection device of claim 17, further comprising a backside power delivery network (BSPDN) on and in electrical contact with the conductive contact.

19. The backside power connection device of claim 18, further comprising nanosheet layer segments adjoining the first source/drain.

20. The backside power connection device of claim 18, further comprising a second replacement metal gate structure on the nanosheet layer segments adjoining the first source/drain.
